(19) United States
(12) Patent Application Publication
(10) Pub. No.: US 2008/0061374 A1
(43) Pub. Date: Mar. 13, 2008

(54) Semiconductor resistor and semiconductor process of making the same

(75) Inventors: Chiu-Chih Chiang, Hsinchu City (TW); Chih-Feng Huang, Zhubei City (TW)

Correspondence Address: NIXON PEABODY LLP - PATENT GROUP, CLINTON SQUARE, P.O. BOX 31051, ROCHESTER, NY, 14603-1051, US

(73) Assignee: System General Corporation, Shindian City (TW)

(21) Appl. No.: 11/516,982

(22) Filed: Sep. 7, 2006

(51) Int. Cl. H01L 29/76

(52) U.S. Cl. 257/371

(57) ABSTRACT

A semiconductor resistor and a semiconductor process of making the same are provided. The semiconductor resistor comprises a substrate, a deep well, at least two contact regions, and a doped region. The substrate is doped with a first type of ions. The deep well is doped with a second type of ions, and formed in the substrate. The contact regions are heavily doped with the second type of ions, and formed in the deep well. The doped region is doped with the first type of ions, and is separated from the deep well by a distance. Wherein the first type of ions and the second type of ions are complementary, and the distance between the deep well and the doped region adjusts the breakdown voltage. In addition, the semiconductor process comprises the steps of forming a deep well containing a first type of ions; forming a doped region containing a second type of ions; forming an oxide layer; and forming at least two contact regions containing the first type of ions in the deep well.

### CROSS-REFERENCES TO RELATED APPLICATIONS

Not applicable.

### BACKGROUND OF THE INVENTION

1. Field of the Invention

The present invention relates to a semiconductor resistor and a semiconductor process of making the same; more specifically, relates to a semiconductor process of fabricating a semiconductor resistor with a high breakdown voltage.

2. Descriptions of the Related Art

Resistors being fabricated on a semiconductor circuit are usually formed by a deep well being formed in a substrate. Referring to FIG. 1 and FIG. 2, FIG. 1 is a top view of a semiconductor resistor 1 of the prior art, and FIG. 2 is a side elevational, cross-sectional view of the portion of the semiconductor resistor 1 of FIG. 1 taken substantially along section line A-A thereof. The semiconductor resistor 1 comprises a P-substrate 10, a deep N-well 11, and a doped region 12 being doped with a p-type of ions. The doped region 12 that is adjacent to the deep N-well 11 will ensure a breakdown voltage of the semiconductor resistor 1 on a fixed value.

However, for improving the breakdown voltage of the semiconductor resistor 1, an ion concentration of the deep N-well 11 will be reduced. Therefore, there are extra masks and processes to fabricate the semiconductor resistor I with reduced ion concentration, and costs will be increased. Furthermore, the semiconductor resistor 1 will have a larger variation and a bigger voltage coefficient.

According to the above description, there is a need in this industry to improve a high breakdown voltage of a semiconductor resistor without extra masks and processes to increase costs.

### SUMMARY OF THE INVENTION

One object of this invention is to provide a semiconductor resistor with a breakdown voltage. The semiconductor resistor comprises a substrate, a deep well, at least two contact regions, and a doped region. The substrate is doped with a first type of ions. The deep well is doped with a second type of ions, and formed in the substrate. The contact regions are heavily doped with the second type of ions, and formed in the deep well. The doped region is doped with the first type of ions, and is separated from the deep well by a distance. Wherein the first type of ions and the second type of ions are complementary, and the distance between the deep well and the doped region adjusts the breakdown voltage.

Another object of this invention is to provide a semiconductor process for forming a semiconductor resistor. The semiconductor process comprises the steps of forming a deep well containing a first type of ions; forming a doped region containing a second type of ions; forming an oxide layer; and forming at least two contact regions containing the first type of ions in the deep well. Wherein the first type of ions and the second type of ions are complementary, an ion concentration of one of the contact regions is higher than that of the deep well, and the doped region and the deep well are separated a distance.

The present invention provides a doped region that is separated from a deep well by a distance to increase a breakdown voltage of a semiconductor resistor. And the distance between the doped region and the deep well can adjust the breakdown voltage. In addition, extra masks and processes are not needed, and costs will be reduced.

The detailed technology and preferred embodiments implemented for the subject invention arc described in the following paragraphs accompanying the appended drawings for people skilled in this field to well appreciate the features of the claimed invention.

### BRIEF DESCRIPTION OF THE DRAWINGS

FIG. 1 illustrates a top view of a semiconductor resistor of the prior art;

FIG. 2 illustrates a cross-section view of the semiconductor resistor of the prior art;

FIG. 3 illustrates a top view of a first embodiment of the present invention;

FIG. 4 illustrates a cross-section view of the first embodiment of the present invention; and

FIG. 5 illustrates a flow chart of a second embodiment of the present invention.

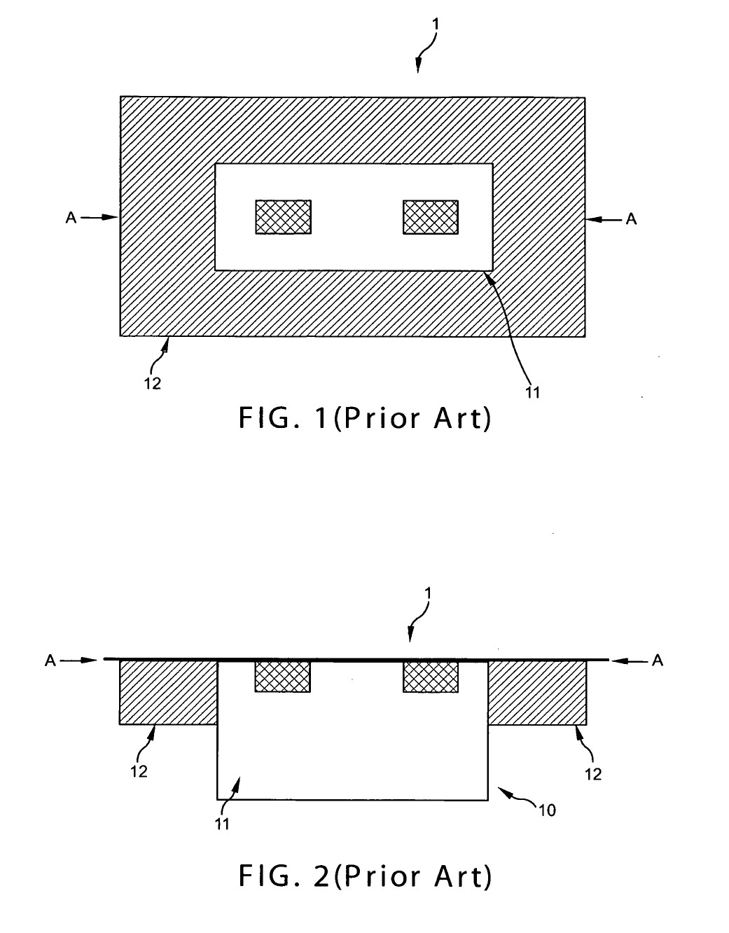

### DESCRIPTION OF THE PREFERRED EMBODIMENT

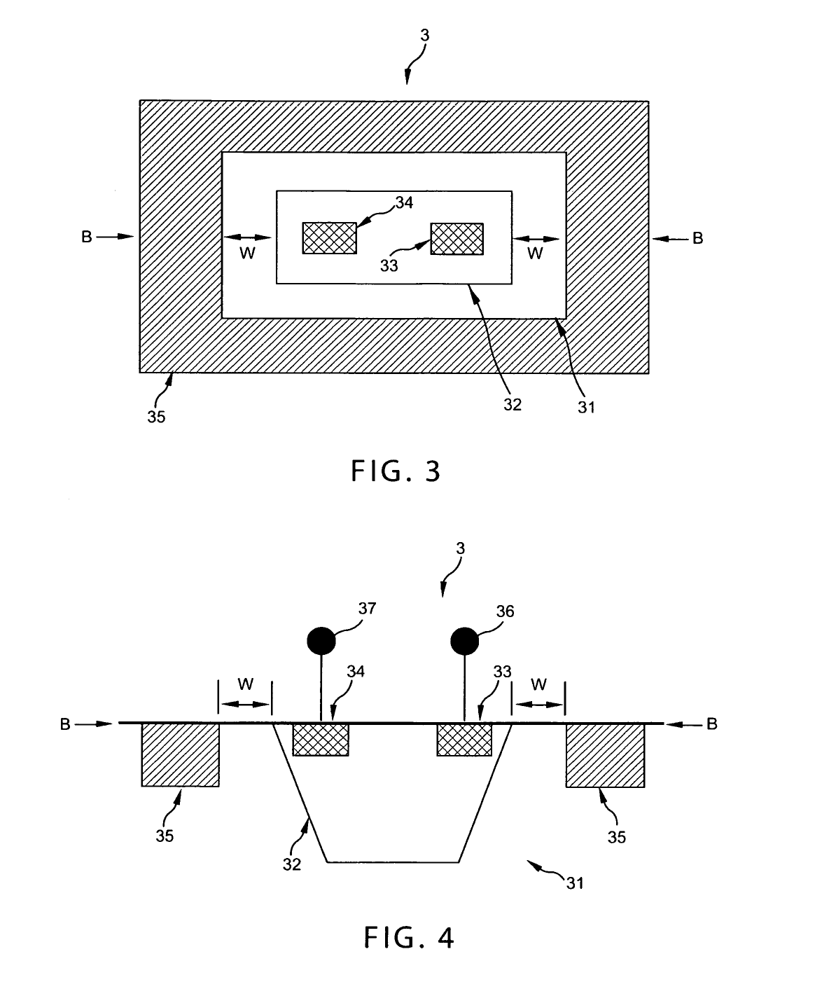

A first embodiment of the present invention is a semiconductor resistor 3 as illustrated in FIG. 3 and FIG. 4. FIG. 3 is a top view of the semiconductor resistor 3, and FIG. 4 is a side elevational, cross-sectional view of the portion of the semiconductor resistor 3 of FIG. 3 taken substantially along section line B-B thereof. The semiconductor resistor 3 comprises a P-substrate 31, a deep N-well 32, two contact regions 33, 34, a doped region 35, and two electrodes 36, 37. The P-substrate 31 is doped with a p-type of ions. The deep N-well 32 is doped with an n-type of ions, and formed in the P-substrate 31. The contact regions 33, 34 are heavily doped with the n-type of ions, and formed in the deep N-well 32. The doped region 35 is doped with the p-type of ions, and is separated from the deep N-well 32 by a distance W. The electrodes 36, 37 are connected to the contact regions 33, 34 separately.

According to the above description, parameters of the semiconductor resistor 3 are as follows, a range of the ion concentration of the deep N-well 32 is from 1E12 to 5E13 per square centimeter, a range of a depth of the deep N-well 32 is from 2 to 10 um, a range of the ion concentration of each of the contact regions 33,34 is from 1E15 to 5E16 per square centimeter, a range of an ion concentration of the doped region 35 is from 1E12 to 3E13 per square centimeter, a range of a depth of the doped region 35 is from 1 to 5 um, and a range of the distance W is from 0 to 20 um.

The distance W between the deep N-well 32 and the doped region 35 adjusts a breakdown voltage of the semiconductor resistor 3. When the distance W increases, the breakdown voltage also increases. In conditions of determined ion concentrations and depths of each region, the breakdown voltage stops increasing till the distance W exceeds a predetermined value.

Although the above embodiment takes the p-type of ions as the P-substrate 31 and the doped region 35, and takes the n-type ions as the deep N-well 32 and the contact regions 23, 24. Those skilled in the art can easily understand that the n-type of ions and the p-type of ions are configured to be complementary. The p-type of ions can be replaced by the n-type of ions, and the n-type of ions can be replaced correspondingly by the p-type of ions, so that the replacement forms a complementary structure of the first embodiment and still works.

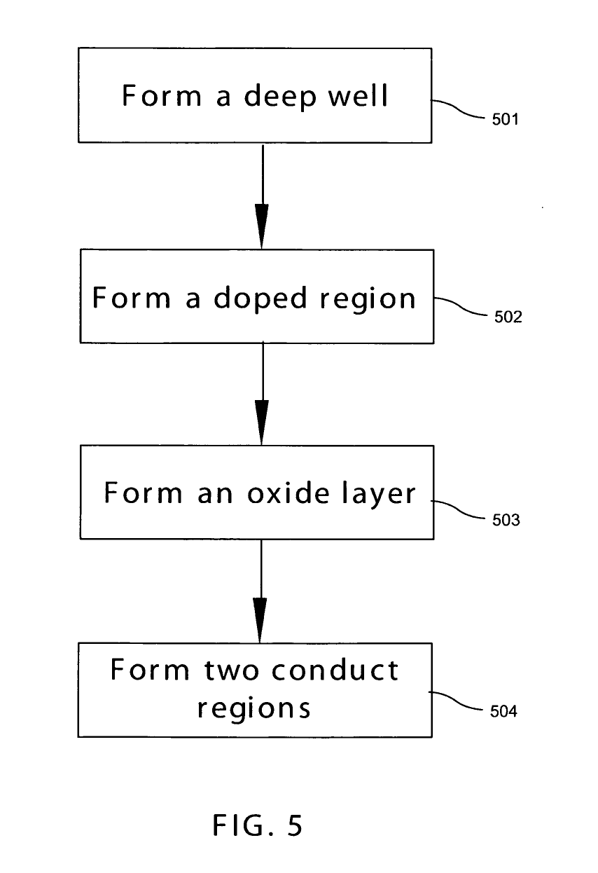

A second embodiment of the present invention is a semiconductor process for forming a semiconductor resistor as illustrated in FIG. 5. First, step 501 is executed to form a deep well containing a first type of ions, such as the deep N-well 32, in a P-substrate. Then, step 502 is executed to form a doped region containing a second type of ions, such as one of the doped region 35. The step 501, 502 can be achieved by thermal driving for 6 to 12 hours under 1000 to 1200 degrees of Celsius. Step 503 is executed to form an oxide layer. Finally, step 504 is excuted to form two contact regions containing the first type of ions in the deep well, such as the contact regions 33, 34.

Wherein the first type of ions and the second type of ions are complementary, an ion concentration of one of the contact regions is higher than that of the deep well, and the doped region and the deep well are separated a distance. Alternatively, the doped region may be formed before the deep well being formed. That is, step 501 can be executed posterior to step 502. Moreover, the sequence of the aforementioned steps is for the purpose of an example. The sequence is not intended to be a limitation of the present invention.

Accordingly, the present invention is capable to provide a semiconductor resistor with a high breakdown voltage. The corresponding semiconductor processes are also provided. A doped region being doped the p-type of icons of the semiconductor resistor is separated from a deep N-well of the same by a distance to increase the breakdown voltage. And the distance between the doped region and the deep well can adjust the breakdown voltage. The present invention can achieve the goal without extra masks and processes.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A semiconductor resistor with a breakdown voltage, comprising:
a substrate being doped with a first type of ions;
a deep well being doped with a second type of ions, and formed in the substrate;
at least two contact regions being heavily doped with the second type of ions, and formed in the deep well; and
a doped region being doped with the first type of ions, and being separated from the deep well by a distance;
wherein the first type of ions and the second type of ions are complementary, the distance between the deep well and the doped region adjusts the breakdown voltage, and the breakdown voltage stops increasing when the distance exceeds a predetermined value.

2. (canceled)

3. The semiconductor resistor as claimed in claim 1, wherein a range of the ion concentration of the deep well is from 1E12 to 5E13 per square centimeter.

4. The semiconductor resistor as claimed in claim 1, wherein a range of a depth of the deep well is from 2 to 10 um.

5. The semiconductor resistor as claimed in claim 1, wherein a range of the ion concentration of each of the contact regions is from 1E15 to 5E16 per square centimeter.

6. The semiconductor resistor as claimed in claim 1, wherein a range of an ion concentration of the doped region is from 1E12 to 3E13 per square centimeter.

7. The semiconductor resistor as claimed in claim 1, wherein a range of a depth of the doped region is from 1 to 5 um.

8. The semiconductor resistor as claimed in claim 1, wherein a range of the distance is from a value large than zero to 20 um.

9. A semiconductor process for forming a semiconductor resistor, comprising the steps of:
forming a deep well containing a first type of ions;
forming a doped region containing a second type of ions;
forming an oxide layer; and
forming at least two contact regions containing the first type of ions in the deep well;
wherein the first type of ions and the second type of ions are complementary, an ion concentration of one of the contact regions is higher than that of the deep well, and the doped region and the deep well are separated a distance.

10. The semiconductor process of claim 9, wherein the step of forming the deep well further comprises the step of:
thermal driving for 6 to 12 hours under 1000 to 1200 degrees of Celsius.

11. The semiconductor process of claim 9, wherein the step of forming the doped region further comprises the step of:
thermal driving for 6 to 12 hours under 1000 to 1200 degrees of Celsius.

12. A semiconductor resistor with a breakdown voltage, comprising:
a substrate doped with a first type of ions;
a well doped with a second type of ions and formed in the substrate, the first type of ions and the second type of ions are complementary;
at least two contact regions doped with the second type of ions and formed in the well; and
a doped region doped with the first type of ions and separated from the well by a distance greater than zero.

13. The semiconductor resistor as claimed in claim 12 wherein the distance the doped region is separated from the well is a distance in a range of distances to substantially obtain a particular breakdown voltage for the breakdown voltage.
